(19) United States
(12) Patent Application Publication
(10) Pub. No.: US 2012/0137976 A1
(43) Pub. Date: Jun. 7, 2012

(54) HOT ZONE DEVICE

(76) Inventors: Jyh-Chen Chen, Jhongli City (TW); Ying-Yang Teng, Jhongli City (TW); Chung-Wei Lu, Jhongli City (TW); Hsueh-I Chen, Jhongli City (TW)

(21) Appl. No.: 12/958,475

(22) Filed: Dec. 2, 2010

(51) Int. Cl. C23C 16/455

(52) U.S. Cl. 118/726

(57) ABSTRACT

The present invention relates to a hot zone device for use in a crystal-growing furnace. The hot zone device has a gas inlet. The gas inlet is mounted in an insulation layer at a position above the crucible in a manner protruding into an interior of the crucible. The insulation layer is formed with a gas exit. The gas inlet is positioned such that the opening thereof is spaced apart from the free surface of the melt contained in the crucible by a distance substantially equal to or shorter than 10 cm, so as to allow the free surface of the melt to be blown by the guided gas flow in such a manner that the gas flow takes the impurity away from the free surface efficiently. As a result, the crystal ingot obtained by solidifying the melt will exhibit a reduced concentration of impurities and an improved crystal quality.

### BACKGROUND OF THE INVENTION

1. Field of the Invention

The present invention relates to a hot zone device for producing a crystal ingot, and more particularly, to a hot zone device that is capable of effectively reducing the impurities present in the crystal ingot produced thereby.

2. Description of the Prior Art

It is known in the art that a solar cell is a non-pollutant renewable energy source that can directly generate electric power by virtue of the interactions between the sunlight and chemical materials. Especially, the solar cell will not discharge any undesired waste gas during use, such as CO₂, so that the solar cell is promising in helping environmental protection and solving the problem of the earth's greenhouse effect.

A solar cell is a device that is capable of converting the solar energy into electrical power by generating a potential difference at the P-N junction interface of a semiconductor device, rather than by transmission of electrically conductive ions via an electrolyte. The semiconductor device will generate a tremendous amount of electrons when struck by the sunlight, and the movement of the electrons results in a potential difference at the P-N junction.

The modern solar cells are typically made by three types of materials: amorphous materials, mono-crystal materials and poly-crystal materials. FIG. 1 illustrates a furnace for producing a silicon crystal ingot, which primarily includes a crucible 21 for containing a silicon melt 11. The crucible 21 is provided circumferentially with a lateral insulation layer 22 and an upper insulation layer 23, so as to constitute a hot zone, in which a heater 24 are equipped to provide heat to silicon.

The upper insulation layer 23 is further provided with a gas inlet 25 used for introducing an inert gas, whereas the lateral insulation layer 22 may be formed with a gas exit 26. During the process of melting the silicon by heat, a gas is introduced into the furnace at a predetermined flow rate through the gas inlet 25 to generate a gas flow passing through the hot zone and, thus, carrying the impurity away from the furnace via the gas exit 26.

A crystal ingot 12 may be obtained by reducing the output power of the heater 24 (casting process), or by moving the lateral insulation layer 22 upwards to allow radiant cooling of the crucible 21 (directional solidification system process), to thereby solidify the silicon melt 11 contained within the crucible 21.

Moreover, the crystal ingot 12 may also be obtained by additionally disposing a support 28 between the crucible 21 and a base 27, so that the silicon melt 11 contained within the crucible 21 can be solidified by lowering the support 28 to draw the crucible 21 downwards to a cooling zone (Bridgman process), or by introducing a cooling fluid into the support 28 (heat exchanger process).

In the conventional furnace described above, however, the gas inlet 25 of the hot zone device only slightly protrudes into the hot zone beneath the upper insulation layer 23. As a consequence, the opening of the gas inlet 25 is located so far from the free surface of the silicon melt 11 contained in the crucible 21 (namely, the interface of the silicon melt and the gas) that the gas flow introduced through the gas inlet 25 fails to effectively carry the impurities away from the free surface and leads to an unfavorable result that the crystal ingot produced thereby has a high concentration of impurities and a reduced crystal quality.

### SUMMARY OF THE INVENTION

Accordingly, an object of the invention is to provide a hot zone device for use in a crystal-growing furnace that is capable of improving the quality of the crystal ingot produced thereby by effectively reducing the impurities present in the crystal ingot.

In order to achieve this object, a hot zone device is provided, which comprises an insulation layer enclosing a crucible, a gas inlet for introducing an inert gas, which is mounted in the insulation layer at a position above the crucible in a manner protruding into an interior of the crucible, and a gas exit formed in the insulation layer, so that the gas inlet is allowed to introduce a gas at a predetermined flow rate to generate a gas flow passing through the hot zone and carrying the impurity away from the furnace via the gas exit.

Especially, the gas inlet is arranged to protrude into the crucible in such a manner that the opening thereof is spaced apart from the free surface of the melt contained in the crucible by a distance substantially equal to or shorter than 10 cm. As a result, at a given gas flow rate, the impurities can be efficiently and rapidly taken away from the free surface of the melt by the gas flow according to the invention disclosed herein as compared to the prior art. As a result, the crystal ingot thus obtained exhibits a reduced concentration of impurities and an improved crystal quality.

Preferably, the hot zone device according to the invention additionally comprises an adjusting unit coupled to the gas inlet. The adjusting unit allows a precise control of the position of the gas inlet in relation to either the height of crucible or the height of the free surface of the melt during an actual operation, so as to maintain the opening of the gas inlet spaced apart from the free surface of the melt contained in the crucible by a distance substantially equal to or shorter than 10 cm.

Preferably, the hot zone device according to the invention additionally comprises a guide plate extending outwardly from the opening of the gas inlet at a predetermined angle with respect to the gas inlet. As such, the free surface of the melt is blown by the guided gas flow in such an effective manner that the crystal ingot thus produced exhibit a reduced concentration of impurities.

### BRIEF DESCRIPTION OF THE DRAWINGS

The above and other objects, features and effects of the invention will become apparent with reference to the following description of the preferred embodiments taken in conjunction with the accompanying drawings, in which:

FIG. 1 is a schematic structural diagram illustrating the hot zone device used in a conventional crystal-growing furnace;

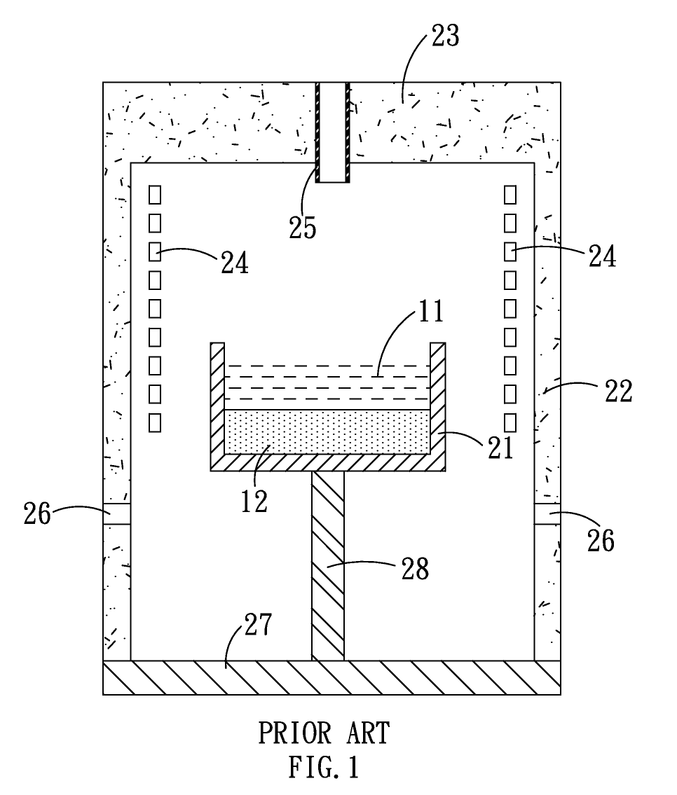

FIG. 2 is a schematic cross-sectional view of the hot zone device according to the first preferred embodiment of the invention;

FIG. 3 is a schematic cross-sectional view of the hot zone device according to the second preferred embodiment of the invention;

FIG. 4 is a schematic cross-sectional view of the hot zone device according to the third preferred embodiment of the invention;

FIG. 5 is a schematic cross-sectional view of the hot zone device according to the fourth preferred embodiment of the invention;

FIG. 6 is a schematic diagram showing the contours of the crucible and the guide plate according to the fifth preferred embodiment of the invention;

FIG. 7 is a schematic diagram showing the contours of the crucible and the guide plate according to the sixth preferred embodiment of the invention; and

FIG. 8 shows the concentration profiles of impurities simulated along the growth direction of grown crystal ingots under different gas inlet designs.

### DETAILED DESCRIPTION OF THE PREFERRED EMBODIMENTS

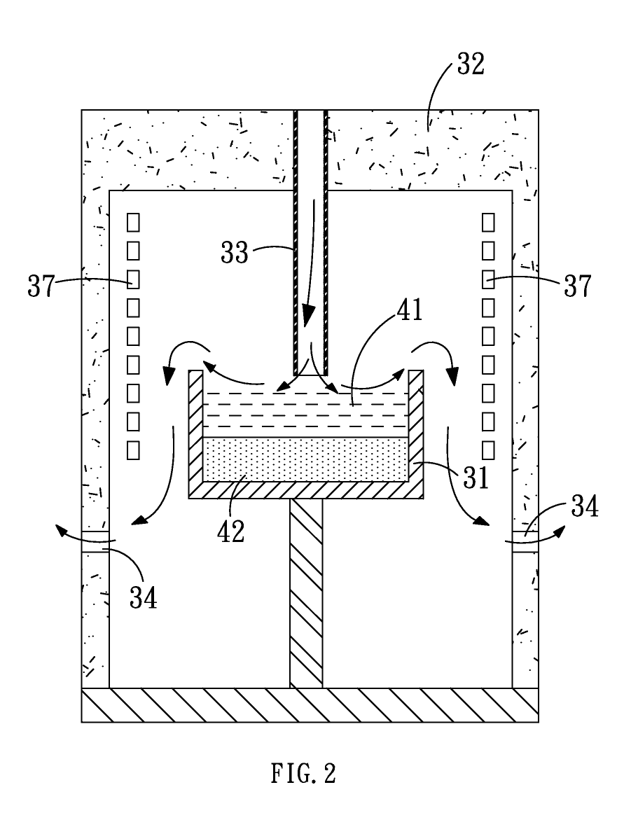

The present invention provides a crystal-growing furnace for producing a silicon crystal ingot. As shown in FIG. 2, the furnace according to the invention generally comprises a crucible 31 for containing a silicon melt 41. The crucible 31 is surrounded circumferentially by an insulation layer 32, so as to constitute a hot zone, in which a heater 37 are equipped to provide heat to silicon.

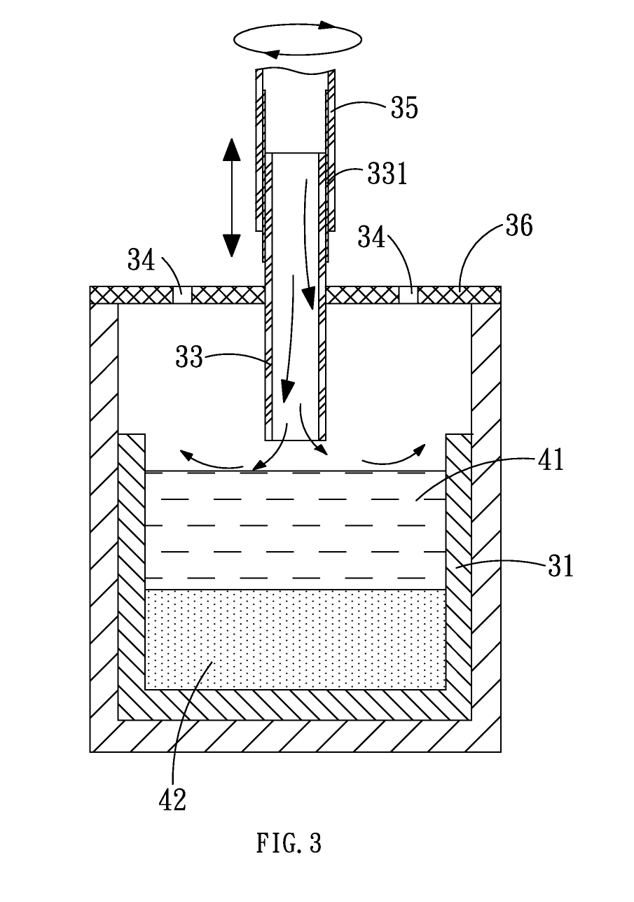

The hot zone device according to the invention has a gas inlet 33 for introducing an inert gas, which is mounted in the insulation layer 32 at a position above the crucible 31 in a manner protruding into an interior of the crucible 31, and a gas exit 34 formed in the insulation layer 32, so that the gas inlet 33 is allowed to introduce a gas at a predetermined flow rate to generate a gas flow passing through the hot zone and carrying the impurity away from the furnace via the gas exit 34. The crucible 31 may be provided above with a cover 36 formed with a gas exit 34, as shown in FIG. 3.

The hot zone device is characterized in that the gas inlet 33 is positioned such that the opening thereof is spaced apart from the free surface of the melt 41 (namely, the interface of the melt 41 and the gas) contained in the crucible 31 by a distance substantially equal to or shorter than 10 cm. As a result, at a given gas flow rate, the impurities can be more efficiently taken away from the free surface of the melt 41 by the gas flow according to the invention disclosed herein as compared to the prior art. The crystal ingot 42 obtained by solidifying the melt 41 exhibits a reduced concentration of impurities and an improved crystal quality.

During the actual practice, the hot zone device according to the invention is applicable to solidify the melt 41 contained within the crucible 31 by reducing the output power of the heater (casting process), or to solidify the melt 41 contained within the crucible 31 by moving the insulation layer 32 upwards to effect radiant cooling of the crucible 31 (directional solidification system process). Alternatively, the hot zone device according to the invention may be additionally provided with a support (not shown) connected to an underside of the crucible 31, so that the melt 41 contained within the crucible 31 can be solidified by lowering the support to draw the crucible 31 downwards to a cooling zone (Bridgman process), or by introducing a cooling fluid into the support (heat exchanger process). All of these can effectively reduce the concentration of impurities present in the crystal ingot 42 produced by solidifying the melt 41, thereby improving crystal quality of the crystal ingot 42.

Preferably, the hot zone device according to the invention additionally includes an adjusting unit coupled to the gas inlet 33 and used to adjust the position of the gas inlet 33 in relation to the crucible 31. The adjusting unit includes an internally threaded sleeve 35 inserted substantially vertically into the insulation layer 32. The gas inlet 33 is provided on its outer surface with a threaded section 331 for engaging the threaded sleeve 35, so that the relative position of the gas inlet 33 can be adjusted by rotating the gas inlet 33 in relation to the threaded sleeve 35. By virtue of the arrangement disclosed herein, the inventive hot zone device allows a precise control of the position of the gas inlet 33 in relation to the height of crucible 31 or the height of the free surface of the melt 41 during an actual operation, so as to maintain the opening of the gas inlet 33 spaced apart from the free surface of the melt 41 contained in the crucible 31 by a distance substantially equal to or shorter than 10 cm.

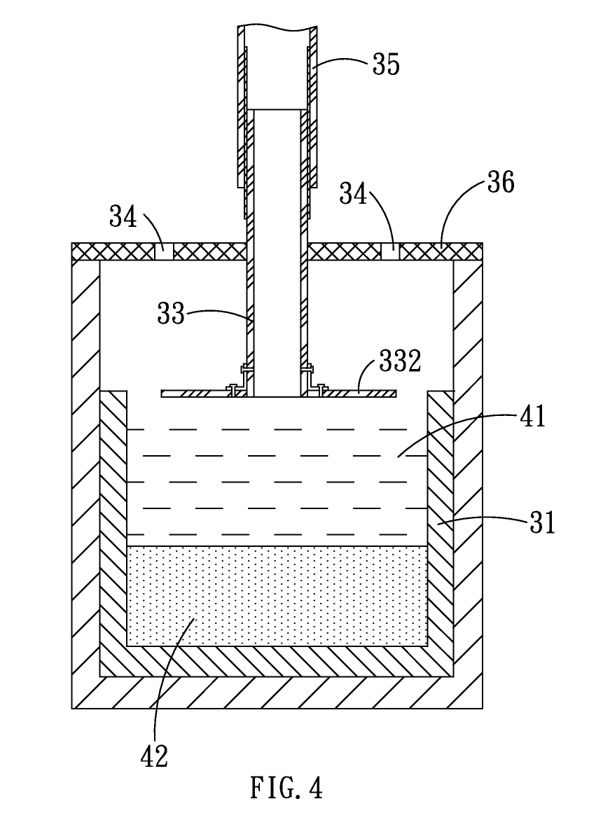

It should be noted that the inventive hot zone device may further include a guide plate 332 extending outwardly from the opening of the gas inlet 33 at a predetermined angle with respect to the gas inlet 33 as shown in FIG. 4, so that the free surface of the melt 41 is blown by the guided gas flow in such an effective manner that the crystal ingot thus produced exhibit a reduced concentration of impurities.

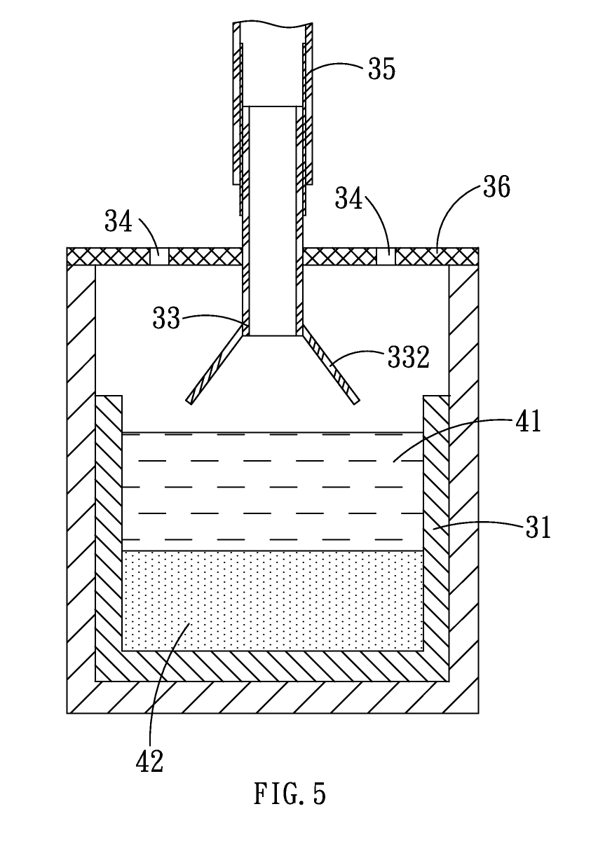

During an actual practice as shown in FIG. 4, the guide plate 332 extends outwardly at an angle of 90° with respect to the gas inlet 33. As an alternative, the guide plate 332 may extend outwardly at an angle of 150° with respect to the gas inlet 33, as shown in FIG. 5. In both cases shown in FIGS. 4 and 5, the gas inlet 33 is coupled with an adjusting unit for adjusting the relative position of the gas inlet 33.

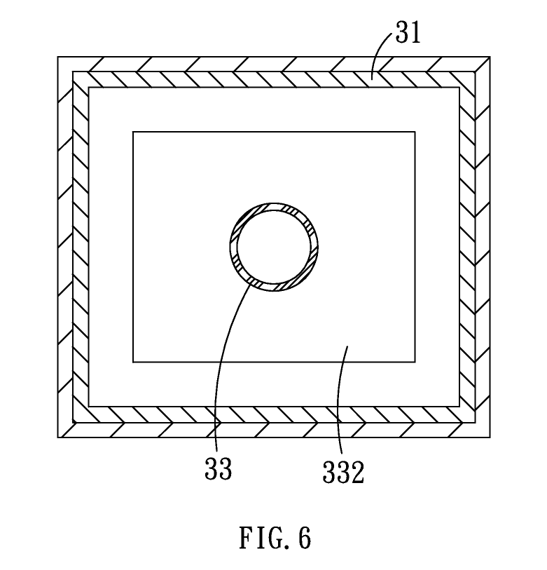

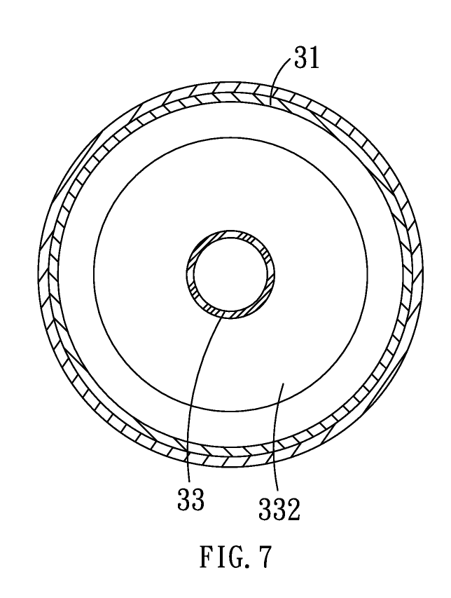

Preferably, the guide plate 332 is configured to have a rectangular outer contour and the crucible 31 is similarly configured to have a rectangular internal contour, as shown in FIG. 6. Alternatively, the guide plate 332 is configured to have a circular outer contour and the crucible 31 is similarly configured to have a circular internal contour, as shown in FIG. 7. The free end of the guide plate 332 is kept apart from the internal wall of the crucible 31 by a predetermined distance.

The inventive hot zone device is designed to make the gas inlet 33 protrude into the crucible 31 in such a manner that the opening of the gas inlet 33 is spaced apart from the free surface of the melt 41 contained in the crucible 31 by a distance substantially equal to or shorter than 10 cm. As a result, at a given gas flow rate, the impurities can be more rapidly and more efficiently taken away from the free surface of the melt 41 by the gas flow according to the invention disclosed herein as compared to the prior art. The hot zone device disclosed herein enables the gas flow introduced through the gas inlet 33 to be guided by the guide plate 332, so that the free surface of the melt 41 is blown by the guided gas flow in such an effective manner that the crystal ingot thus produced exhibit a reduced concentration of impurities.

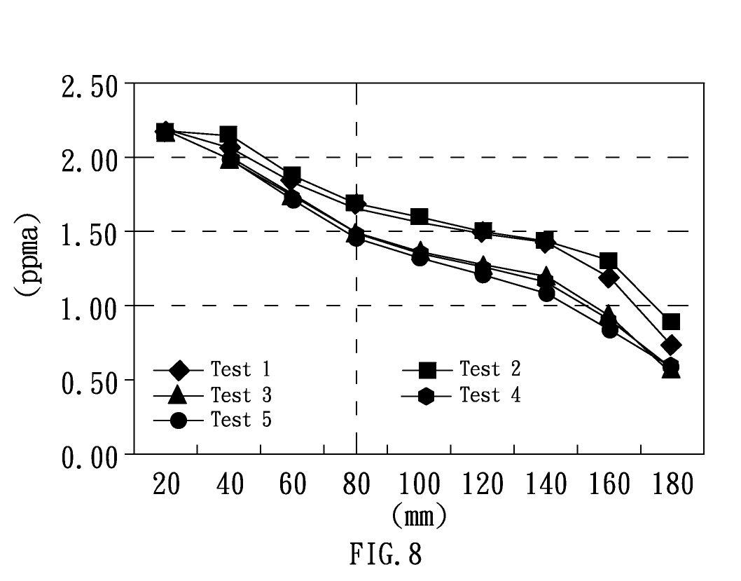

FIG. 8 shows the concentration profiles of impurities measured along the growth direction of grown crystal ingots under different gas inlet designs, in which crystal ingots produced by using a conventional gas inlet design (Test 1) and by using the designs where the opening of the gas inlet is spaced apart from the free surface of the melt contained in the crucible by a distance of 15 cm (Test 2), 10 cm (Test 3), 5 cm (Test 4) and 3 cm (Test 5), respectively, are subjected to the measurement. At a certain height of grown crystal ingots (for example, at a height of 80 mm along the growth direction) , the crystal ingots obtained in Test 1 and Test 2 both contain an impurity concentration of about 1.6 ppma, while those obtained in Tests 3-5 contain an impurity concentration of about 1.45 ppma. The results indicate that the inventive hot zone device, which is tailored to make the gas inlet 33 protrude into the crucible 31 in such a manner that the opening of the gas inlet 33 is spaced apart from the free surface of the melt 41 contained in the crucible 31 by a distance substantially equal to or shorter than 10 cm, can efficiently enable the production of crystal ingots with a reduced concentration of impurities and, thus, an improved crystal quality.

In conclusion, the hot zone device for use in a crystal-growing furnace as disclosed herein achieves the intended objects and effects of the invention by virtue of the structural arrangements described above. While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. A hot zone device, comprising:
a crucible having an interior containing a melt;
an insulation layer enclosing the crucible and formed with a gas exit; and
a gas inlet for introducing an inert gas, the gas inlet having an opening and being positioned such that the opening is spaced apart from a free surface of the melt contained in the crucible by a distance substantially equal to or shorter than 10 cm.

2. The hot zone device according to claim 1, wherein the gas inlet is coupled with an adjusting unit for positioning the gas inlet relative to the melt.

3. The hot zone device according to claim 2, wherein the adjusting unit comprises a threaded sleeve inserted into the insulation layer, and wherein the gas inlet is provided on its outer surface with a threaded section for engaging the threaded sleeve, so that the relative position of the gas inlet can be adjusted by rotating the gas inlet in relation to the threaded sleeve.

4. The hot zone device according to claim 1, further comprising a guide plate extending outwardly from the opening of the gas inlet at a predetermined angle with respect to the gas inlet.

5. The hot zone device according to claim 1, further comprising a guide plate extending outwardly from the opening of the gas inlet at an angle of 90° with respect to the gas inlet.

6. The hot zone device according to claim 1, further comprising a guide plate extending outwardly from the opening of the gas inlet at an angle of 150° with respect to the gas inlet.

7. The hot zone device according to claim 1, further comprising a guide plate extending outwardly from the opening of the gas inlet at a predetermined angle with respect to the gas inlet, wherein the guide plate is configured to have a rectangular outer contour and the crucible is similarly configured to have a rectangular internal contour.

8. The hot zone device according to claim 1, further comprising a guide plate extending outwardly from the opening of the gas inlet at a predetermined angle with respect to the gas inlet, wherein the guide plate is configured to have a circular outer contour and the crucible is similarly configured to have a circular internal contour.

9. The hot zone device according to claim 1, wherein the crucible is provided above with a cover formed with a gas exit.
